(19) United States
(12) Patent Application Publication
(10) Pub. No.: US 2025/0309138 A1
(43) Pub. Date: Oct. 2, 2025

(54) PROTECTIVE DIELECTRIC LAYER CRACK MITIGATION THROUGH STRESS SINGULARITY FIELD REDUCTION

(71) Applicant: Texas Instruments Incorporated, Dallas, TX (US)

(72) Inventors: Yutaka Suzuki, Allen, TX (US); Jens Lohse, Allen, TX (US); Kozaburo Sakai, Allen, TX (US); Rajen Manicon Murugan, Dallas, TX (US)

(21) Appl. No.: 18/621,819

(22) Filed: Mar. 29, 2024

(51) Int. Cl. H01L 23/00; H01L 23/10

(52) U.S. Cl. CPC H01L 23/562; H01L 23/10

(57) ABSTRACT

A microelectronic device may have a protective dielectric layer over the top metal layer of the microelectronic device which provides a portion of a hermetic seal between the microelectronic device and the environment. The protective dielectric layer may also improve resistance to physical damage of the microelectronic device before packaging. The protective dielectric layer may have bond pad openings to allow electrical contact between the microelectronic device to a microelectronic package. The protective dielectric layer may overlap the bond pads to ensure the hermetic seal of the microelectronic device. Cracking of the protective dielectric layer in the region where the protective dielectric layer overlaps the bond pad may lead to failure of the microelectronic device. Stress analysis using finite element methods (FEM) and experimental data show that increasing the overlap of the protective dielectric layer over the bond pad may reduce protective dielectric layer cracking.

### TECHNICAL FIELD

This disclosure relates to the field of semiconductor devices. More particularly, but not exclusively, this disclosure relates to dielectric layers in microelectronic devices.

### BACKGROUND

Dielectric layers may be used to provide electrical isolation between conductive elements of a microelectronic device. Dielectric layers may also be used to provide a protective dielectric layer or protective overcoat (PO) over the microelectronic device which provides a portion of a hermetic seal between the microelectronic device and the environment. Protective dielectric layers may crack in areas of high dielectric layer stress, especially when covering underlying topography. Reduction of stress in protective dielectric layers and elimination of protective dielectric layer cracking over underlying topography is challenging.

### SUMMARY

A microelectronic device may have a protective dielectric layer, sometimes referred to as a protective overcoat (PO) over the microelectronic device. The protective dielectric layer provides a portion of a hermetic seal between the microelectronic device and the environment. The protective dielectric layer may also improve resistance to physical damage of the microelectronic device before packaging. The protective dielectric layer may have bond pad openings to allow contact between bond pads of the microelectronic device and a microelectronic package. The protective dielectric layer may overlap the bond pads to ensure the hermetic seal of the microelectronic device. The protective dielectric layer may be a single dielectric film or a stack of multiple dielectric films. Silicon nitride, silicon oxynitride, other suitable dielectrics, or a combination thereof may be present as a part of the protective dielectric layer.

Stress analysis using finite element methods (FEM) and fabrication of semiconductor devices both show that increasing the overlap of the protective dielectric layer over the bond pads reduces the dielectric stress of the protective dielectric layer as it covers the bond pad topography may result in reduced cracking of the protective dielectric layer. An unexpected result from the FEM analysis beyond that of an overall reduction dielectric stress is a change in the location of maximum stress from a corner of the protective dielectric layer as it covers the underlying bond pad topography to a location away from the corner of the protective dielectric layer.

Protective dielectric layer stress may also be reduced by changing the sidewall angle of the bond pad under the protective dielectric layer. Both stress analysis and experimental results show that a decrease of the bond pad angle (from a near vertical bond pad sidewall profile to a trapezoidal profile) reduces the stress of the protective dielectric layer near the bond pad opening and may result in reduced cracking of the protective dielectric layer.

### BRIEF DESCRIPTION OF THE FIGURES

FIG. 1A is a cross section of a microelectronic device including a microelectronic component, an interconnect system, a top meal layer and a protective dielectric layer.

FIG. 1B is a cross section focusing on the protective dielectric layer overlap at the edges of a top metal layer bond pad with increased overlap of the protective dielectric layer over the metal top metal layer bond pad edges, including FEM analysis of the region of maximum stress.

FIG. 1C is a cross section of a portion of the cross section in FIG. 1B, highlighting the region of maximum dielectric stress.

FIG. 2 is a cross section focusing on the protective dielectric layer overlap at the edges of a top metal layer bond pad for a bond pad with a bond pad sidewall which is less than the sidewall angle of FIG. 1A-FIG. 1C, including FEM analysis of the region of maximum stress.

FIG. 3 is a graph comparing the maximum stress of the protective dielectric layer and the protective dielectric layer overlap of a bond pad.

FIG. 4 is a graph comparing the maximum stress of the protective dielectric layer and the bond pad sidewall angle.

FIG. 5 is a graph comparing the location of maximum stress of the protective dielectric layer compared to protective dielectric layer overlap of the bond pad.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the examples illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure may be illustrated by examples directed to active devices, it is not intended that these illustrations be a limitation on the scope or applicability of the present disclosure. It is not intended that the active devices of the present disclosure be limited to the physical structures illustrated. These structures are included to demonstrate the utility and application of the present disclosure to various examples.

It is noted that terms such as top, bottom, over, above, and under may be used in this disclosure. These terms should not be construed as limiting the position or orientation of a structure or element, but should be used to provide spatial relationship between structures or elements. The terms “lateral” and “laterally” refer to directions parallel to a plane corresponding to a surface of a layer, for example a top surface of a semiconductor substrate. Moreover, the term “approximately,” as used herein, may refer to ±5% to ±10% variations of the recited values in some cases. In other cases, the term “approximately” may refer to ±10% to ±20% variations of the recited values. Microelectronic devices are being continually improved to reliably operate with higher performance and smaller feature sizes.

A microelectronic device may have a protective dielectric layer which may also be referred to as a protective overcoat (PO) over the top metal layer of the microelectronic device. The protective dielectric layer provides a portion of a hermetic seal between the microelectronic device and the environment. The protective dielectric layer may also improve resistance to physical damage of the microelectronic device before in packaging. The protective dielectric layer may have bond pad openings in the protective dielectric layer over bond pads in the top layer of metal to allow contact between the bond pads of the microelectronic device and a microelectronic package. The protective dielectric layer may overlap the bond pads to ensure the hermetic seal of the microelectronic device. The protective dielectric layer may be a single dielectric layer or a stack of multiple dielectric layers. Silicon nitride, silicon oxynitride, silicon dioxide, silicon carbide aluminum oxide, or other suitable dielectric materials may be present as a part of the hermetic seal of the protective dielectric layer.

Cracking of protective dielectric layer, especially dielectric layers such as silicon nitride and silicon oxynitride which provide the hermitic seal between the microelectronic device and the environment may lead to failure of the microelectronic device. In the region near the protective dielectric layer overlap of the bond pad, it may be convenient to view the continuous protective dielectric layer as consisting of several portions. A first portion of the protective dielectric layer which overlaps the top surface of the bond pad, a second portion in which the protective dielectric layer covers the sidewall of the bond pad, and finally a third portion, adjacent to the second portion, the third portion of the protective dielectric layer being over the interconnect system. A protective dielectric layer corner is formed between the protective dielectric layer transition between the second portion covering the bond pad sidewall and the third portion where the protective dielectric layer covers the interconnect region. The protective dielectric layer corner may be of various angles depending on the underlying topography and the conformality of the protective dielectric layer.

Protective dielectric layer stress may cause cracking to occur in regions of high dielectric stress, the protective dielectric layer stress generally being higher in regions where the protective dielectric layer transitions over areas of underlying topography such as around the bond pads. If the protective dielectric stress is higher than the mechanical stability of the protective dielectric layer, cracking of the protective dielectric may occur.

Protective dielectric layer stress analysis using finite element methods (FEM) and fabrication of semiconductor devices both show that increasing the overlap of the protective dielectric layer over the bond pads may decrease the magnitude of the maximum protective dielectric stress of the protective dielectric layer as it covers the bond pad topography resulting in a crack free protective dielectric layer. An unexpected result from the FEM analysis beyond that of an overall reduction dielectric stress is a change in the location of maximum stress from a corner of the protective dielectric layer as it covers the underlying bond pad topography to a location away from the corner of the protective dielectric layer. Where the protective dielectric layer overlap of the bond pad is equal to or greater than twice the bond pad thickness, protective dielectric layer cracking may be reduced compared to when the protective dielectric layer overlap of the bond pad is less than twice the bond pad thickness.

Protective dielectric layer stress analysis using FEM and fabrication of semiconductor devices show that decreasing the bond pad sidewall angle i.e., making the bond pad sidewall more sloped, also decreases the magnitude of the maximum protective dielectric layer stress. Where the bond pad sidewall angle is less than seventy-five degrees and the protective dielectric layer overlap of the bond pad is equal to or greater than the bond pad thickness, a protective dielectric layer may be formed with fewer cracks than when the bond pad sidewall angle is greater than seventy-five degrees and the protective dielectric layer overlap of bond pad is equal to the bond pad thickness.

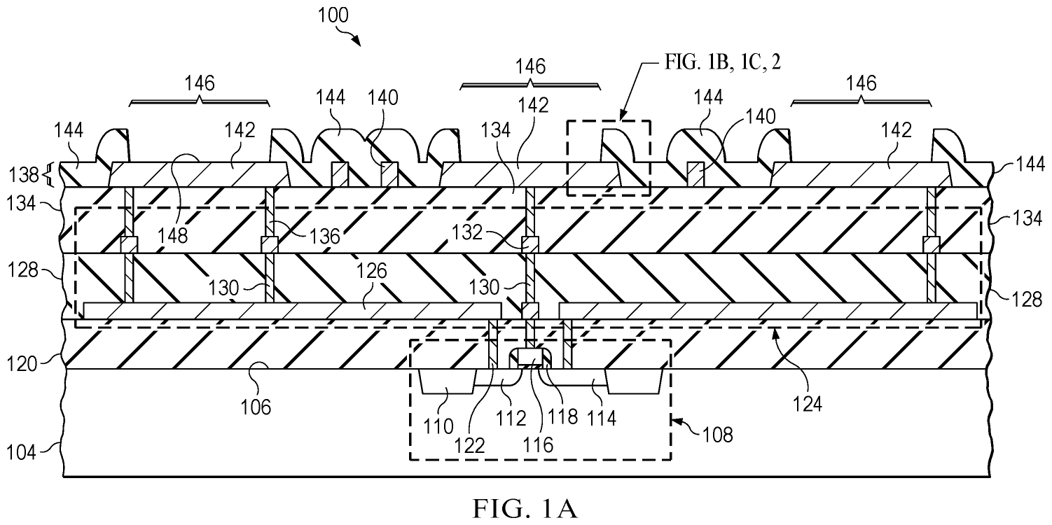

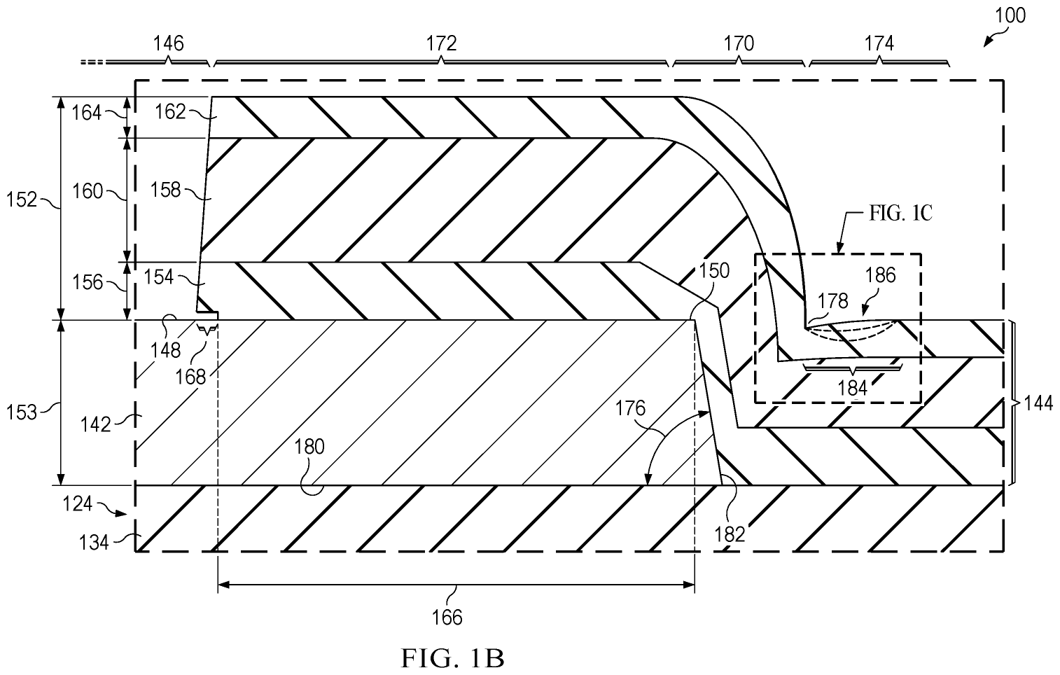

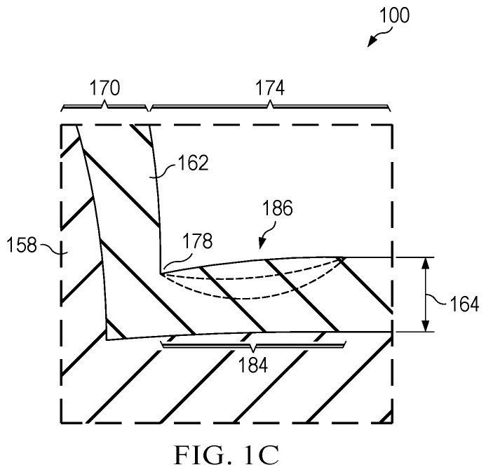

FIG. 1A is a cross section of an example microelectronic device 100 after formation. The microelectronic device 100 includes a bond pad 142. The bond pad 142 may be of aluminum or any other suitable electrically conducting material. The bond pad 142 may electrically connect the microelectronic device 100 to a semiconductor package (not specifically shown). A protective dielectric layer 144 forms a portion of a hermetic seal surrounding the microelectronic device 100. Other portions of the hermetic seal such as a scribe seal are not specifically shown. The microelectronic device 100 including a substrate 104 with a top surface 106 and a microelectronic component 108 extending into the substrate 104. The microelectronic component 108 may be manifested as an integrated circuit, a discrete component such as a power transistor, a passive component such as a transformer or a filter, a micro electromechanical system (MEMS) component, a sensor, an actuator, a microfluidic component, or an electro-optical component such as a micro-mirror array component, by way of example. The microelectronic component 108 of the example microelectronic device 100 includes an NMOS transistor which may be formed by any suitable method. The example NMOS transistor includes shallow trench isolation 110, a source region 112 a drain region 114, a gate dielectric (not specifically shown), a gate electrode 116, and gate sidewalls 118. A pre metal dielectric (PMD) 120 is over the microelectronic component 108. Contacts 122 in the PMD make electrical connections between the microelectronic component 108 and an interconnect system 124. The interconnect system 124 formed using any suitable technique, typically an aluminum-based interconnect system or a copper-based interconnect system. The example interconnect system 124 of the example microelectronic device 100 is typical of an aluminum-based interconnect system. While interconnect systems may have various numbers of metal layers, the example interconnect system 124 consists of two metal layers, consisting of a first metal layer 126, a first intermetal dielectric layer 128, a first via level 130, a second metal level 132, a second intermetal dielectric layer 134, and a second via level 136. A top metal layer 138 is on the interconnect system 124 and is in electrical contact with the interconnect system 124. The top metal layer 138 may have top metal routing 140 and may have bond pads 142. The protective dielectric layer 144 is formed over the top metal layer 138. A bond pad etch process (not specifically shown) removes a portion of the protective dielectric layer 144 over the bond pads 142 and forms a bond pad opening 146 which exposes a top surface 148 of the bond pad 142. The top metal routing 140 remains covered by the protective dielectric layer 144. The protective dielectric layer 144 may consist of one or more layers of a dielectric material such as silicon dioxide, silicon nitride, silicon oxynitride, silicon carbide, aluminum oxide or other suitable dielectric material.

FIG. 1B is a cross section of a portion of FIG. 1A. FIG. 1B highlights the region where the protective dielectric layer 144 overlaps a bond pad top edge 150. In FIG. 1B, the protective dielectric layer overlap of the bond pad 166 is greater than twice the bond pad thickness 153. The protective dielectric layer 144 has a protective dielectric layer thickness 152. The protective dielectric layer 144 may be a layer of a single dielectric (not specifically shown), or may be made of multiple dielectric layers. In the example microelectronic device 100, the protective dielectric layer 144 contains three layers. The first protective dielectric layer 154 is on the interconnect system 124, a portion of the bond pad 142, and on the top metal routing 140 (referred to in FIG. 1A). The first protective dielectric layer 154 is a high-density plasma (HDP) silicon dioxide layer with a first protective dielectric layer thickness 156. A second protective dielectric layer 158 is on the first protective dielectric layer 154 and has second protective dielectric layer thickness 160. The second protective dielectric layer 158 may be a plasma enhanced tetraethylorthosilane (TEOS) based layer. A third protective dielectric layer 162 is on the second protective dielectric layer 158 and has a third protective dielectric layer thickness 164. The third protective dielectric layer 162 may be silicon nitride, silicon oxynitride, aluminum oxide, or other suitable dielectric material.

The protective dielectric layer 144 has a protective dielectric layer overlap of the bond pad 166 which covers the bond pad top edge 150 and a region around the perimeter of the bond pad 142, extending from the bond pad top edge 150 towards the center of the bond pad and terminating at a bond pad undercut region 168 if present. If the protective dielectric layer 144 does not have a bond pad undercut region 168, the protective dielectric layer overlap of the bond pad 166 extends from the bond pad top edge 150 towards the center of the bond pad and terminates at the bond pad opening 146. The bond pad undercut region 168 may be formed between the top surface 148 of the bond pad 142 and a portion of the protective dielectric layer 144 nearest the bond pad opening 146.

The protective dielectric layer 144 has protective dielectric layer topography region 170 as the protective dielectric layer 144 transitions from a protective dielectric layer region over the bond pad region 172 over the bond pad top edge 150 and onto a protective dielectric layer over the interconnect system region 174 over the interconnect system 124. A bond pad sidewall angle 176 influences the slope of the protective dielectric layer topography region 170. The bond pad sidewall angle 176 is the angle formed between the bottom surface 180 of the bond pad 142 and the bond pad sidewall 182. For example, a bond pad 142 with a bond pad sidewall angle 176 of ninety degrees would have a bond pad sidewall 182 which is vertical. If the bond pad sidewall angle 176 is above seventy-five degrees, a protective dielectric layer corner 178 may have an angle near ninety degrees where the protective dielectric layer topography region 170 meets the protective dielectric layer over interconnect system region 174.

Increasing the protective dielectric layer overlap of the bond pad 166 reduces the level of protective dielectric cracking in the protective dielectric layer topography region 170 and the protective dielectric layer over the interconnect system region 174. An unexpected result from FEM analysis is that there is both a reduction in protective dielectric layer 144 maximum stress by over an order of magnitude, and a shift in a maximum dielectric stress region 186 from the protective dielectric layer corner 178, to a point over in the protective dielectric layer over the interconnect system region 174 as the protective dielectric layer overlap of the bond pad 166 is increased from a protective dielectric layer overlap of the bond pad 166 on the order of the bond pad thickness 153, to a protective dielectric layer overlap of the bond pad 166 equal to or greater than twice the bond pad thickness 153. Lines of equivalent stress 184 from the FEM analysis show the region of maximum dielectric stress region 186 when the protective dielectric layer overlap of the bond pad 166 is equal to or greater than twice the bond pad thickness 153. Experimental data confirms the FEM analysis, with no cracking of the protective dielectric layer 144 for overlaps equal to or greater than twice the bond pad thickness 153.

FIG. 1C is a close-up cross-sectional view showing the lines of equivalent stress 184 of the protective dielectric layer 144 of FIG. 1B. FEM analysis (shown in lines of equivalent stress 184) shows that when the protective dielectric overlap of the bond pad 166 (referred to in FIG. 1B) is equal to or greater than twice the protective dielectric layer thickness 152, the region of maximum dielectric stress region 186 shifts from the protective dielectric layer corner 178 to an area of the protective dielectric layer over the interconnect system region 174. Additionally, the FEM analysis show in addition to moving the region of maximum stress from the protective dielectric layer corner 178 to a region over the protective dielectric layer over the interconnect system region 174, the maximum stress is reduced by over an order of magnitude with respect to the maximum stress when the protective dielectric overlap of the bond pad to the maximum stress when the protective dielectric layer overlap of the bond pad 166 (referred to in FIG. 1B) is on the order of the thickness of the protective dielectric layer 144.

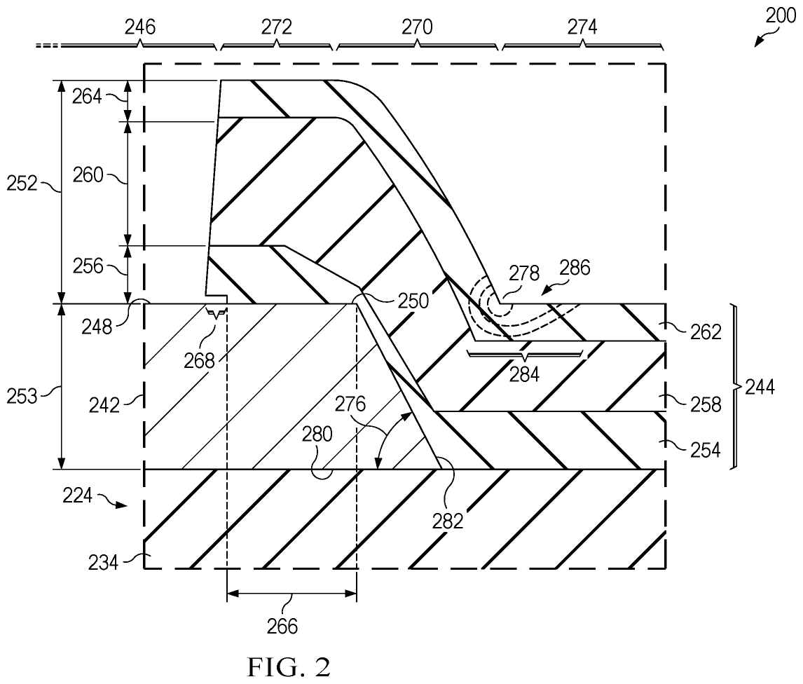

FIG. 2 is a cross section of a portion of FIG. 1A of a second embodiment in which a protective dielectric layer overlap of the bond pad 266 is equal to or greater than a bond pad thickness 253, and a bond pad sidewall angle 276 is less than seventy-five degrees. A protective dielectric layer 244 has a protective dielectric layer thickness 252. The protective dielectric layer 244 may be a layer of a single dielectric, or may be made of multiple layers. In the example microelectronic device 200, the protective dielectric layer 244 is contains three layers. A first protective dielectric layer 254 is on a second intermetal dielectric layer 234, the second intermetal dielectric layer 234 being the top layer of an interconnect system 224. The first protective dielectric layer 254 is also on a portion of the bond pad 242. The first protective dielectric layer 254 is an HDP silicon dioxide layer with a first protective dielectric layer thickness 256. A second protective dielectric layer 258 is on the first protective dielectric layer 254 and has a second protective dielectric layer thickness 260. The second protective dielectric layer 258 may be a plasma enhanced TEOS based layer. A third protective dielectric layer 262 is on the second protective dielectric layer 258 and has a third protective dielectric layer thickness 264. The third protective dielectric layer 262 may be silicon nitride, silicon oxynitride, aluminum oxide, or other suitable dielectric material.

The protective dielectric layer 244 has a protective dielectric layer overlap of the bond pad 266 which covers the bond pad top edge 250 and a region around the perimeter of the bond pad 242, extending from the bond pad top edge 250 towards the center of the bond pad and terminating at a bond pad undercut region 268 if present. If the protective dielectric layer 244 does not have a bond pad undercut region 268, the protective dielectric layer overlap of the bond pad 266 extends from the bond pad top edge 250 towards the center of the bond pad and terminates at the bond pad opening 246. The bond pad undercut region 268 may be formed between the top surface 248 of the bond pad 242 and a portion of the protective dielectric layer 244 nearest the bond pad opening 246.

The protective dielectric layer 244 has a protective dielectric layer topography region 270 as the protective dielectric layer 244 transitions from a protective dielectric layer region over the bond pad 272 over the bond pad top edge 250 and onto a protective dielectric layer over the interconnect system region 274 over the interconnect system 224. The bond pad sidewall angle 276 influences the slope of the protective dielectric layer topography region 270.

The bond pad sidewall angle 276 is the angle formed by the bottom surface 280 of the bond pad 242 and the bond pad sidewall 282. FEM analysis shows that as the bond pad sidewall angle 276 is decreased from eighty-five degrees to less than seventy-five degrees, the magnitude of the FEM lines of equivalent stress 284 is reduced by more than fifty percent for a given protective dielectric layer overlap of the bond pad 266.

Unlike the case referred to in FIG. 1B and FIG. 1C in which an increase in the protective dielectric layer overlap of bond pad 166 to equal to or greater than twice the bond pad thickness 153 and a bond pad sidewall angle 176 equal to or greater than seventy-five degrees results in a reduction in magnitude of the maximum dielectric stress region 186 and a shift in the location of the maximum dielectric stress region 186 from the protective dielectric layer corner 178 to a location in the protective dielectric layer over the interconnect system region 174, FIG. 2 shows that a reduction in the bond pad sidewall angle 276 to less than seventy-five degrees and a protective dielectric layer overlap of the bond pad 266 equal or greater than the bond pad thickness 253 results in a region of maximum dielectric stress region 286 at the protective dielectric layer corner 178, but the reduction in bond pad sidewall angle 276 to less than seventy-five degrees reduces the FEM lines of equivalent stress 284 to approximately half the stress of when the bond pad sidewall angle 276 is eighty-five degrees. Confirming the FEM analysis, experimental data shows that dielectric stress in the maximum dielectric stress region 286 is reduced and results in a protective dielectric layer 244 which is crack free at the protective dielectric layer corner 278 and in the protective dielectric layer over the interconnect system region 274 when the bond pad angle is less than seventy-five degrees, and the protective dielectric layer overlap of the bond pad 266 is equal to or greater than the bond pad thickness 253.

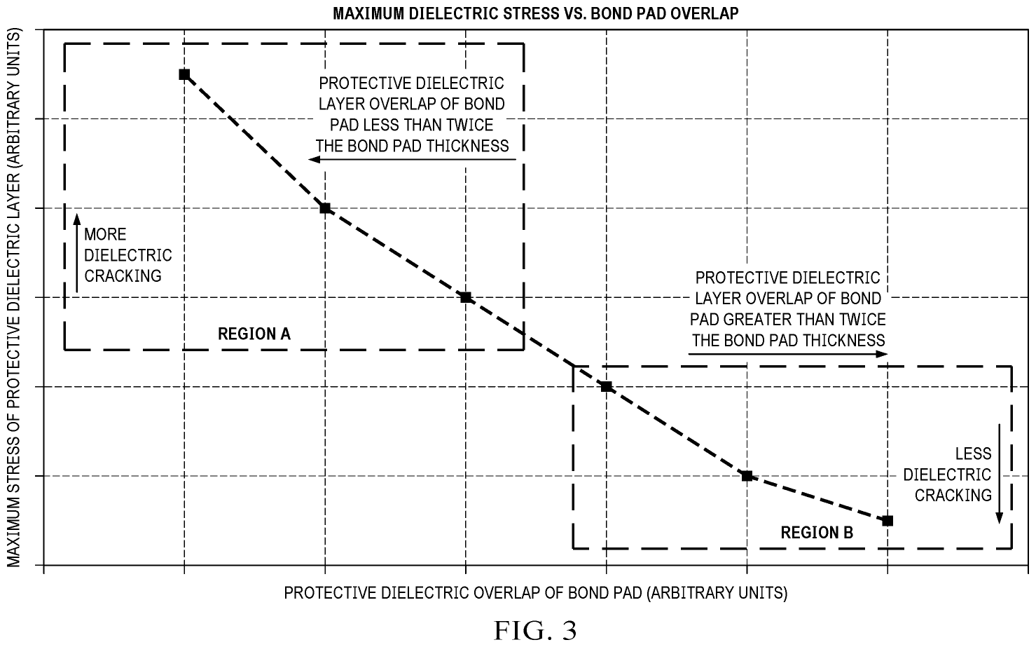

FIG. 3 shows a graph based on FEM analysis of the protective dielectric layer 144 maximum dielectric stress region 186 for the example microelectronic device 100 shown in FIG. 1B and FIG. 1C which is corroborated by experimental data comparing the maximum dielectric stress region 186 of the protective dielectric layer 144 (all layers are referenced to in FIG. 1B) as a function of the protective dielectric layer overlap of the bond pad 166 for a bond pad 142 with a bond pad sidewall angle 176 equal to or greater than seventy-five degrees.

As shown in the FIG. 3 (region A), in the upper left-hand portion of FIG. 3, a region is shown in which the protective dielectric layer overlap of the bond pad 166 is less than twice the bond pad thickness 153, and the maximum dielectric stress region 186 is such that cracking of the protective dielectric layer 144 at the protective dielectric layer corner 178 or in the protective dielectric region over the interconnect system region 174 may occur as observed in experimentally formed microelectronic devices 100. Region B, in the lower right-hand portion of the FIG. 3, is a region in which the protective dielectric layer overlap of the bond pad 166 is equal to or greater than twice the bond pad thickness 153, and the maximum dielectric stress region 186 is such that the protective dielectric layer 144 at the protective dielectric layer corner 178 or in the protective dielectric region over the interconnect system region 174 may be free of any protective dielectric layer 144 cracking in experimentally formed microelectronic devices 100.

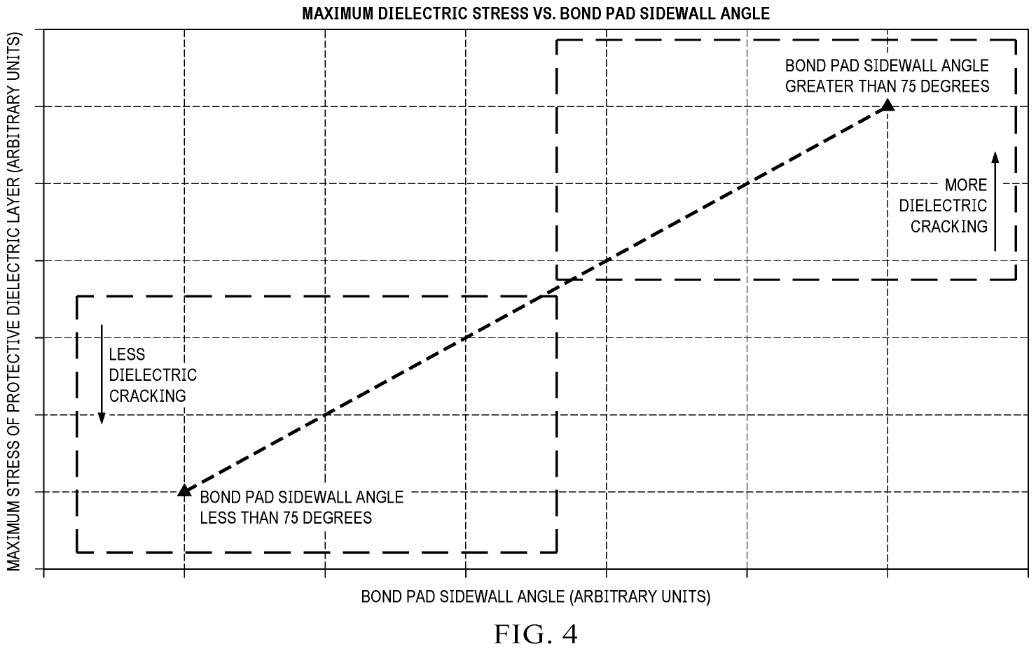

FIG. 4 shows a graph based on FEM stress analysis of the protective dielectric layer 244 of the example microelectronic device 200 shown in FIG. 2 which is corroborated by experimental data comparing the maximum dielectric stress region 286 of the protective dielectric layer 244 (all layers are referenced to in FIG. 2) as a function of the bond pad sidewall angle 276 in the case where the protective dielectric layer overlap of the bond pad 266 is equal to the bond pad thickness 253.

As shown in the FIG. 4, region A, in the upper right-hand portion of FIG. 4, a region is shown in which the bond pad sidewall angle 276 is equal to or greater than seventy-five degrees and the maximum dielectric stress region 286 is such that cracking of the protective dielectric layer 244 at the protective dielectric layer corner 278 or in the protective dielectric layer over the interconnect system region 274 may occur, with results confirmed in experimentally. Region B, in the lower left-hand portion of the FIG. 4, is a region where the bond pad sidewall angle 276 is less than seventy-five degrees, and the maximum dielectric stress region 286 is such that the protective dielectric layer 244 at the protective dielectric layer corner 278 or in the protective dielectric layer over the interconnect system region 274 is free of any protective dielectric layer 244 cracking with results confirmed in experimentally.

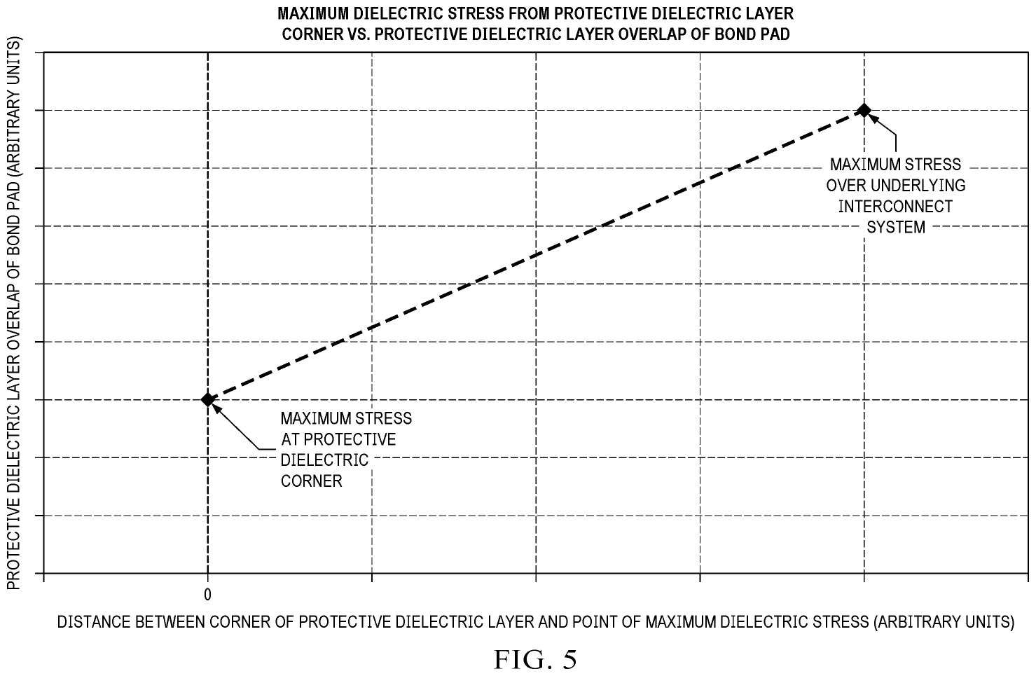

FIG. 5 refers to the microelectronic device 100 shown in FIG. 1B and FIG. 1C. FIG. 5 compares the distance of maximum dielectric stress region 186 of the protective dielectric layer 144 from the protective dielectric layer corner 178 of the protective dielectric layer 144 as a function of the protective dielectric layer overlap of the bond pad 166. The bond pad sidewall angle 176 is eighty-five degrees for all data points in FIG. 5. In FIG. 5 the FEM analysis of the protective dielectric layer 144 maximum dielectric stress region 186 shows that the maximum dielectric stress region 186 moves from the protective dielectric layer corner 178 to a location in the protective dielectric layer over the interconnect system region 174 as the protective dielectric layer overlap of bond pad 166 is increased.

Both the reduction in the magnitude of the maximum dielectric stress region 186 with increased protective dielectric layer overlap of bond pad 166 (referred in FIG. 3) to more than twice the bond pad thickness 153, and movement of the maximum dielectric stress region 186 from the protective dielectric layer corner 178 to a location in the protective dielectric layer over the interconnect system region 174 shown in FIG. 5 are factors which can contribute to the formation of a protective dielectric layer 144 which is free from protective dielectric layer 144 cracking.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A microelectronic device, comprising:
a substrate; the substrate including a semiconductor material;
a semiconductor component extending into the semiconductor material;
an interconnect region on the semiconductor component;
a top metal layer on the interconnect region in electrical contact with the interconnect region, wherein a portion of the top metal layer includes a bond pad, the bond pad having a top surface, a thickness and top surface edges;
a protective dielectric layer on the top metal layer; and
a protective dielectric layer opening over a portion of the bond pad,
wherein the protective dielectric layer has a protective dielectric layer overlap of the bond pad extending from the top surface edges of the bond pad towards a center of the bond pad, the protective dielectric layer overlap of the bond pad being equal to or greater than twice the bond pad thickness.

2. The microelectronic device of claim 1, wherein the protective dielectric layer is a single dielectric layer consisting of a dielectric layer selected from the group consisting of silicon nitride, silicon oxynitride, silicon carbide, and aluminum oxide.

3. The microelectronic device of claim 1, wherein the protective dielectric layer consists of a plurality of dielectric layers, the plurality of dielectric layers selected from the group consisting of silicon dioxide, silicon oxynitride, silicon nitride, silicon carbide, and aluminum oxide.

4. The microelectronic device of claim 1, wherein a protective dielectric layer thickness is between half and twice the bond pad thickness.

5. The microelectronic device of claim 1, wherein the protective dielectric layer is free of a bond pad undercut region.

6. A microelectronic device, comprising:
a substrate; the substrate including a semiconductor material;
a semiconductor component extending into the semiconductor material;
an interconnect region on the semiconductor component;
a top metal layer on the interconnect region in electrical contact with the interconnect region, wherein a portion of the top metal layer includes a bond pad, the bond pad having a top surface, a thickness, top surface edges, and a sidewall angle less than seventy-five degrees;
a protective dielectric layer on the top metal layer; and
a protective dielectric layer opening over a portion of the bond pad,
wherein the protective dielectric layer has a protective dielectric layer overlap of the bond pad extending from the top surface edges of the bond pad towards a center of the bond pad, the protective dielectric layer overlap of the bond pad being equal to or greater than the bond pad thickness.

7. The microelectronic device of claim 6, wherein the protective dielectric layer is a single dielectric layer consisting of a dielectric layer selected from the group consisting of silicon nitride, silicon oxynitride, silicon carbide, and aluminum oxide.

8. The microelectronic device of claim 6, wherein the protective dielectric layer consists of a plurality of dielectric layers, the plurality of dielectric layers selected from the group consisting of silicon dioxide, silicon oxynitride, silicon nitride, silicon carbide, and aluminum oxide.

9. The microelectronic device of claim 6, wherein a protective dielectric layer thickness is between half and twice the bond pad thickness.

10. The microelectronic device of claim 6, wherein the protective dielectric layer is free of a bond pad undercut region.

11. A method of forming a microelectronic device, comprising:
forming a microelectronic component extending into a substrate;
forming an interconnect region on the microelectronic component;
forming a top metal layer on the interconnect region in electrical contact with the interconnect region,
etching a portion of the top metal layer with a top metal layer etch, forming a bond pad having a top surface, a thickness, and top surface edges;
forming a protective dielectric layer on the top metal layer; and
etching a bond pad opening in the protective dielectric layer on a portion of the bond pad, the protective dielectric layer remaining on the bond pad forming a protective dielectric layer overlap of the bond pad with a protective dielectric overlap width between the top surface edges and the bond pad opening, the protective dielectric layer overlap of the bond pad being equal to or greater than twice the bond pad thickness.

12. The method of claim 11, comprising forming the protective dielectric layer, wherein the protective dielectric layer comprises a single dielectric layer consisting of a dielectric layer selected from the group consisting of silicon nitride, silicon oxynitride, silicon carbide, and aluminum oxide.

13. The method of claim 11, comprising forming the protective dielectric layer wherein the protective dielectric layer comprises a plurality of dielectric layers, the plurality of dielectric layers selected from the group consisting of silicon dioxide, silicon oxynitride, silicon nitride, silicon carbide, and aluminum oxide.

14. The method of claim 11, comprising forming the protective dielectric layer wherein the protective dielectric layer is between half and twice the bond pad thickness.

15. The method of claim 11, comprising forming the protective dielectric layer free of a bond pad undercut region.

16. A method of forming a microelectronic device, comprising:
forming a microelectronic component extending into a substrate;
forming an interconnect region on the microelectronic component;
forming a top metal layer on the interconnect region in electrical contact with the interconnect region,
etching a portion of the top metal layer with a top metal layer etch, a bond pad having a top surface, a thickness, top surface edges, and a sidewall angle less than seventy-five degrees;
forming a protective dielectric layer on the top metal layer;
forming a protective dielectric layer on the top metal layer; and
etching a bond pad opening in the protective dielectric layer on a portion of the bond pad, the protective dielectric layer remaining on the bond pad forming a protective dielectric layer overlap of the bond pad with a protective dielectric layer overlap width between the top surface edges and the bond pad opening, the protective dielectric layer overlap of the bond pad being equal to or greater than the bond pad thickness.

17. The method of claim 16, comprising forming the protective dielectric layer, wherein the protective dielectric layer comprises a single dielectric layer consisting of a dielectric layer selected from the group consisting of silicon nitride, silicon oxynitride, silicon carbide, and aluminum oxide.

18. The method of claim 16, comprising forming the protective dielectric layer wherein the protective dielectric layer comprises a plurality of dielectric layers, the plurality of dielectric layers selected from the group consisting of silicon dioxide, silicon oxynitride, silicon nitride, silicon carbide, and aluminum oxide.

19. The method of claim 16, comprising forming the protective dielectric layer wherein the protective dielectric layer is between half and twice the bond pad thickness.

20. The method of claim 16, comprising forming the protective dielectric layer free of a bond pad undercut region.
